(19) United States
(12) Patent Application Publication
(10) Pub. No.: US 2006/0177977 A1
(43) Pub. Date: Aug. 10, 2006

(54) Method for patterning fins and gates in a FinFET device using trimmed hard-mask capped with imaging layer

(75) Inventors: Philip Ching Ho Chan, Kowloon (CN); Mansun Chan, Kowloon (CN); Xusheng Wu, Kowloon (CN); Chuguang Feng, Kowloon (CN)

Correspondence Address: HESLIN ROTHENBERG FARLEY & MESITI PC, 5 COLUMBIA CIRCLE, ALBANY, NY, 12203, US

(73) Assignee: The Hong Kong University of Science and Technology, Kowloon (CN)

(21) Appl. No.: 11/053,223

(22) Filed: Feb. 8, 2005

(51) Int. Cl. H01L 21/8244; H01L 21/336; H01L 21/331

(52) U.S. Cl. 438/238; 438/284; 438/365

(57) ABSTRACT

A capped trimming hard-mask patterning process to form ultra-thin structures can include depositing a hard-mask layer over a layer of patterning material, depositing an imaging layer over the hard-mask layer, patterning the imaging layer and the hard-mask layer, selectively trim etching the hard-mask layer to form a pattern hard mask, and removing the portions of the patterning layer using the pattern hard mask formed from the trimmed hard-mask. Thus, the use of thin imaging layer, that has high etch selectivity to the hard-mask layer, allows the use of trim etch techniques without a risk of hard-mask erosion or the aspect ratio pattern collapse. That, in turn, allows for the formation of the ultra-thin pattern with widths less than the widths of the pattern of the imaging layer.

### FIELD OF THE INVENTION

This invention relates to a method of fabricating semiconductor structures and devices, and in particular to such a method capable of fabricating device structures on a scale below 100 nm. The invention also extends to devices fabricated thereby.

### BACKGROUND OF THE INVENTION

A pervasive trend in modern integrated circuit manufacture is to produce transistors having feature sizes as small as possible. Smaller feature sizes may allow more transistors to be placed on a single substrate. In addition, transistors with smaller feature sizes may function faster and at a lower threshold voltage than transistors having larger feature sizes. However, the reduction of design features to below 100 nm challenges the limitations of conventional semiconductor design, as well as fabrication techniques and methodology. For example, when the gate length of conventional planar metal oxide semiconductor field effect transistors (MOSFETs) is scaled to below 100 nm, problems associated with short channel effects, such as excessive leakage between the source and drain, become increasingly difficult to overcome. New device structures are therefore being explored to improve FET performance and allow further device scaling.

The double-gate (DG) MOSFET is currently considered the most promising candidate for scaling CMOS to and below the 65 nm technology node. In double-gate MOSFETs, two gates may be used to control short channel effects. A Fin-Field-Effect-Transistor (FinFET) is a form of double-gate structure that exhibits good short channel behavior and conventional CMOS compatible process. A FinFET includes a channel formed in a vertical fin.

However, the FinFET DG MOSFET has its own feature size design requirements. The minimum processing dimension is transferred from defining the gate length to the fin-thickness in order to produce satisfactory device characteristics at very small dimensions. From previous studies, it is known that the general requirement is W_{fin}<0.5L_{eff}−6Tₒₓ to avoid significant short channel effects, where W_{fin} is the fin-width, L_{eff} is the effective channel length, and Tₒₓ is the effective gate oxide thickness. Considering 90 nm technology node referring to ITRS'01 (International Technology Roadmap for Semiconductors, see http://public.itrs.net/), L_{eff} is 37 nm and Tₒₓ is 1 nm, the fin width should below 15 nm. The patterning of such small dimensions gives significant challenges to the fabrication technology. Efficient and effective patterning techniques are therefore needed for patterning sub-20 nm fins (or sub-50 nm gates) for FinFET devices and other very small scale semiconductor structures.

Generally, conventional photolithographic processes (e.g., projection lithography and extreme ultraviolet (EUV) lithography) are used to form the transistor. The feature sizes of a transistor, however, may be limited by the image resolution of the photolithographic equipment. Such image resolution is typically dependent on the wavelength of the photolithographic tool. For example, the minimum resolvable feature size of a 248 nm photolithographic tool may be approximately 0.24 microns. As such, in order to obtain a structure with a feature size with a dimension smaller then approximately 0.24 microns, a smaller wavelength photolithographic tool or an electron beam direct writing lithographic tool may need to be used.

However, there are disadvantages with using smaller wavelength photolithographic or electron beam direct writing lithographic tools. For example, photolithographic tools are typically expensive and therefore, purchasing new photolithographic tools for each new development of transistors with reduced feature sizes may be cost prohibitive. Furthermore, smaller wavelength photolithographic tools used to produce such transistors may require substantial process development to produce such small feature sizes. In addition, the materials used for photoresist films and underlying anti-reflective layers may be dependent on the wavelength used with the photolithographic tool and therefore, may need to be revised for consistency with the new photolithographic tools. In some cases, problems, such as poor image resolution, poor etch selectivity, or patterning clarity such as line edge roughness, may arise with such immature technologies and chemistries. As a result, the installation of new photolithographic equipment and its associated chemistry may delay the development of transistors of reduced feature sizes. For electron beam direct writing lithography, the throughput is very low because it uses an electron beam in a direct writing work mode and therefore the equipment resources and manpower are significantly increased. These problems make it difficult to incorporate electron beam direct writing into a practical semiconductor manufacturing process.

### PRIOR ART

With conventional photolithography tools, a photoresist (PR) ashing technique has been proposed to realize an ultra-small feature size. The ashing process is performed after PR patterning and during the ashing the PR is trimmed and reduced PR dimensions are provided. This proposed method is easy to set up and the trimming can be controlled by reactive gas pressure, temperature, and ashing time. However, a difficulty arising from the ashing process is the tendency for PR erosion and pattern collapse during the trim processes. During the trim processes, a significant amount of the resist is normally etched away in a vertical direction, resulting in a substantial weakening and thinning of the PR. This significant reduction of the vertical dimension or thickness of the PR from its untrimmed vertical dimension can promote discontinuity thereof, resulting in the PR being incapable of providing effective masking in the fabrication of the gate. The resist thickness erosion occurs during etch processes. An example of such a prior art processes is described in U.S. Pat. No. 5,965,461.

Another approach to form active lines with small feature size is disclosed, for example, in U.S. Pat. No. 6,706,571. This is called the spacer hard mask technique. The spacer hard mask method is easy to control and the process is simple and compatible with conventional CMOS technology. But only one type of dimension can be defined at one wafer. That is because the spacer hard mask thickness is determined by the chemical vapor deposition (CVD) thickness of the spacer layer as described, for example, in Journal of IEEE Electron Device Letters, Vol. 23, No. 1 (January 2002), pp. 25-27. This problem becomes serious when multiple gate oxide high performance logic devices with different channel lengths need to be controlled to the same degree of precision.

There is therefore a need for an integrated circuit or electronic device that includes smaller, more densely disposed regions or lines, such as gates and fins in sub-50 nm FinFET devices, and for fabrication technologies that are capable of forming such devices in a practical efficient manner that can be used in commercial fabrication environments.

### SUMMARY OF THE INVENTION

According to the present invention there is provided a method of fabricating a semiconductor device comprising, providing a hard-mask layer over a formation layer that is to be patterned to form said device, depositing an imaging layer over the hard-mask layer, patterning the imaging layer and the hard-mask layer in sequence, trim etching the hard-mask layer to form a pattern smaller than that that the imaging layer had defined, and removing portions of the formation layer uncovered by the hard-mask pattern to form thin structures.

Preferably the step of generating the hard-mask layer comprises thermal oxidation of a portion of a silicon formation layer, or depositing a suitable material as the hard-mask layer on the formation layer.

The step of patterning the imaging layer and the hard-mask layer may include using lithography or dry etch techniques to pattern these two layers into a single configuration.

The step of trim etching the hard-mask layer may comprise providing an isotropic wet etch to the hard-mask layer.

In some embodiments the imaging layer and portions of the formation layer are removed by a single etching process, alternatively the imaging layer may be removed to sufficiently expose the formation layer prior to removing portions of the formation layer.

In embodiments of the invention the imaging layer has a thickness between 500 and 2000 angstroms and the hard-mask layer has a thickness between 300 and 3000 angstroms.

According to another aspect of the invention there is provided a method of forming a fin structure in a FinFET semiconductor device in an integrated circuit comprising, providing a silicon layer, providing a hard-mask layer over the silicon layer, providing an imaging layer over the hard-mask layer, patterning the imaging layer and the hard-mask layer in sequence, trim etching the hard-mask layer to form a hard-mask line having a width less than that that the imaging layer had defined, and removing portions of the silicon layer to form fin structures.

In a preferred embodiment the material for the hard-mask layer has a different etching property from the silicon and the imaging layer material.

The step of patterning the imaging layer and the hard-mask layer may include using lithography or dry etch techniques to pattern these two layers into a single configuration.

In embodiments of this aspect of the invention the fin structures have a smallest dimension of 10-30 nm. The imaging layer may have a deposited thickness of between 500 and 2000 angstroms and the hard-mask layer a thickness of between 300 and 3000 angstroms.

According to a further aspect of the invention there is provided a method of forming a gate structure in a semiconductor device in an integrated circuit, the method comprising, providing a gate material layer, depositing a hard-mask layer over the gate material layer, depositing an imaging layer over the hard-mask layer, patterning the imaging layer and the hard-mask layer in sequence, trim etching the hard-mask layer to form a hard-mask line has a width less than that that the imaging layer had defined, and removing portions of the gate material layer to form gate structures.

In embodiments of this invention the material for the hard-mask layer may have a different etching property from the gate material layer and the imaging layer.

The step of patterning the imaging layer and the hard-mask layer may include using lithography or dry etch techniques to pattern these two layers into a single configuration.

In embodiments of the invention the gate structures have a smallest dimension of 20-100 nm. In addition the invention may also include doping a substrate below the gate material layer to form active regions.

The imaging layer may have a deposited thickness between 500 and 2000 angstroms and the hard-mask layer a deposited thickness between 300 and 3000 angstroms.

According to a still further aspect of the invention there is provided a method of preventing hard-mask-shape irregularization and pattern collapse during a trim etch process in the manufacture of a semiconductor device comprising, providing a hard-mask material layer over a formation layer that is to be patterned to form the device, depositing an imaging layer over the hard-mask material layer, patterning the imaging layer and the hard-mask layer in sequence, trim etching the hard-mask layer to form a hard-mask line having a width less than that that the imaging layer had defined, and removing portions of the formation layer uncovered by the hard-mask pattern to form thin structures.

The material for the hard-mask layer may have different etching properties from the formation layer and the imaging layer material.

The step of patterning the imaging layer and the hard-mask layer includes using lithography and dry etch techniques to pattern these two layers into a single configuration.

In embodiments of this aspect of the invention the thin structures formed in the formation layer may have a width of 10-100 nm. The imaging layer may have a thickness between 500 and 2000 angstroms and the hard-mask layer a thickness between 300 and 3000 angstroms.

### BRIEF DESCRIPTION OF THE FIGURES

Some embodiments of the invention will now be described by way of example and with reference to the accompanying drawings, in which:—

FIGS. 1(a) and (b) show (a) a schematic cross-sectional and three dimensional view representation of a portion of an integrated circuit fabricated in accordance with an embodiment of the invention, and (b) a top view,

FIG. 2 is a schematic cross-sectional view representation of a portion of an integrated circuit, showing a deposition step in a fabrication process,

FIG. 3 is a schematic cross-sectional view representation of a portion of an integrated circuit, showing a patterning and etching step in a fabrication process,

FIG. 4 is a schematic cross-sectional view representation of a portion of an integrated circuit, showing an etching step in a fabrication process, and

FIG. 5 is a schematic cross-sectional view representation of a portion of an integrated circuit, showing an ultra-thin structure, such as fins and gates in FinFETs, in a formation step in a fabrication process.

### DETAILED DESCRIPTION OF PREFERRED EMBODIMENTS

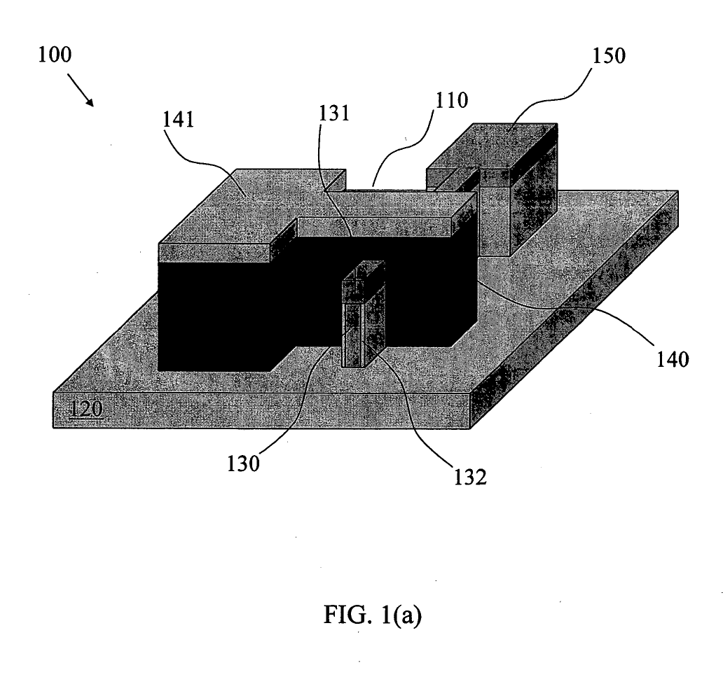

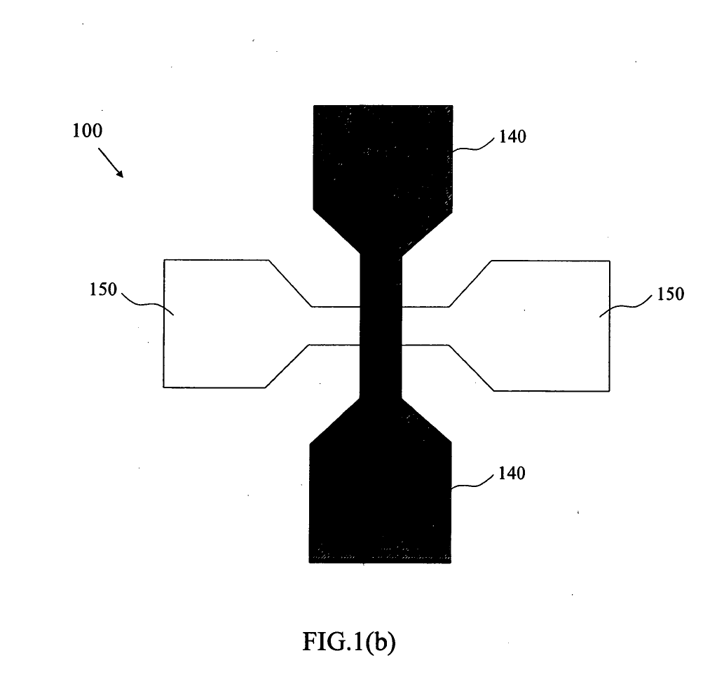

With reference to FIGS. 1(a) and (b), a portion 100 of an integrated circuit includes a semiconductor device in the form of a Fin Field Effect Transistor 110 which is disposed on a substrate 120. The substrate 120 is preferably a semiconductor-on-insulator (SOI) substrate. Alternatively, substrate 120 can be bulk P-type single crystalline (100) or (110) silicon substrate, or any other suitable material for such transistor 110 and integrated circuit depending on the nature of the transistor or other semiconductor device. On the top of fin 130 and gate 140, there are hard masks 131 and 141, which are preferably silicon dioxide, silicon nitride, or other suitable material for blocking the etching of single-crystal or poly-crystal silicon as will be discussed further below.

The FinFET 110 can be a P-channel, N-channel, or intrinsic-channel metal oxide semiconductor field effect transistor (MOSFET). The FinFET 110 is preferably embodied as a Double-Gate-MOSFET and includes a gate 140 structure controlling the two sides of the fin 130 channel body, a source pad region 150, and a drain pad region 150 on the contrary. Only one of the source pad and drain pad regions 150 is shown complete in FIG. 1(a) because the other is shown cutaway to illustrate the cross-section. Both regions and their symmetrical relationship are shown in FIG. 1(b). The dimensions and relative proportions in FIGS. 1(a) and (b) are not shown exactly but for clarity and ease of understanding, but it should be understood that the fin 130 and gate 140 are all of the nanometer scale.

The fin 130 body is initially N- or P-light-doped (e.g., 1×10¹⁵-5×10¹⁸ dopants per cm³) or intrinsic silicon. The fin 130 body has a width of less than 20 nm for sub-50 nm channel length FinFET 110 and a height from 40 nm to 200 nm depending on the device design. The hard-mask 131 on the top of the fin 130 has a thickness of 50-1000 Å. It serves as etching stopper and fin 130 body protector.

For an NMOS FinFET 110, source/drain pad regions 150 and the connected fin regions 130, between S/D pads 150 and gate 140, are heavily doped with N-type dopants (e.g., 5×10¹⁹-2×10²⁰ dopants per cm³). For a PMOS FinFET 110, source/drain pad regions 150 and the connected fin regions 130, between S/D pad 150 and gate 110, are heavily doped with P-type dopants (e.g., 5×10¹⁹-2×10²⁰ dopants per cm³). An appropriate dopant for a PMOS FinFET 110 is boron, boron diflouride, or iridium, and an appropriate dopant for an NMOS FinFET 110 is arsenic, phosphorous, or antimony. Source and drain regions 150 can be raised or enlarged in order to reduce the series resistance. The raised or enlarged material can be self-doped (or not) poly-crystal silicon, silicon germanium, or other suitable materials.

The gate 140 conductor has a thickness of 1000-3000 Å depending on the fin 130 height and a width of less than 50 nm (e.g., channel length). The gate 140 conductor can be a poly-crystal silicon material implanted with dopants or in situ doped (an N-type dopant, such as phosphorous, arsenic or other dopant, a P-type dopant, such as boron, boron diflouride, or other dopant.). Alternatively, the gate 140 conductor can be any other semi-conductive or metal material capable of providing the desired device electrical characteristics.

Gate dielectric layer 132 is preferably a 10 to 100 Å thick thermally grown silicon dioxide layer. Alternatively, it can be a silicon nitride layer or a layer comprised of a high-k dielectric material such as a 2-10 nm thick conformal layer of tantalum pentaoxide (Ta₂O₅), aluminum oxide (Al₂O₃), titanium dioxide (TiO₂) or any other material having a dielectric constant (k) over 8.

To reduce the resistance, a silicide layer can be disposed above source region 150, drain region 150, and gate conductor region 140 after removal of the hard-mask layer 131 and 141 on top of them. Preferably, a nickel silicide NiSiₓ is utilized. Alternatively, the silicide layer can be any type of refractory metal and silicon combination, such as, a cobalt silicide, tungsten silicide, titanium silicide, or other silicide material.

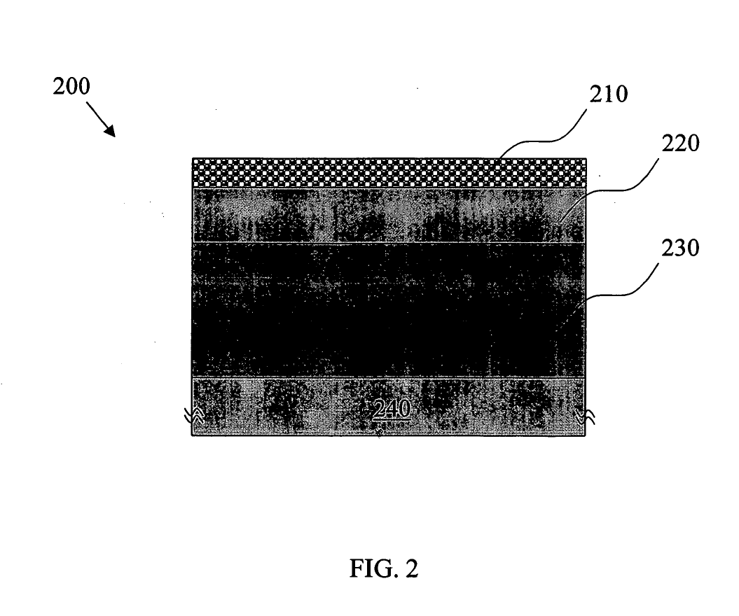

Referring to FIG. 2, a schematic cross-sectional view representation of a portion 200 of an integrated circuit (IC) prior to fabrication includes an imaging layer 210, a hard-mask layer 220, a formation layer 230 and a substrate layer 240. This portion 200 can, for example, be the starting material for fin 130 formation, the mesne process material for gate 140 construction, or any other material that must be fabricated into a very thin line pattern.

The formation layer 230 can be any of a variety of materials which can serve as a portion of fin 130 or gate 140 structure (FIGS. 1(a) and (b)) depending on the final device being fabricated. For the fin patterning case shown as the example in FIG. 2, the formation layer 230 can be original single crystalline silicon on insulator and have a thickness of 400-2000 Å. In this case the substrate layer 240 is an insulator layer. For the gate 140 patterning case, the formation layer 230 can be poly-crystalline silicon and have a thickness of 1000-3000 Å. Alternatively, the formation layer 230 can be substituted by other materials suitable for a gate conductor. This formation layer 230 can be deposited on the substrate by chemical vapor deposition (CVD) or sputter deposition. The substrate layer 240 contains the portions under the gate material.

A hard-mask layer 220 is provided on top of the formation layer 230 and may be formed of a thermal oxide (TO) or low temperature oxide (LTO) layer, a CVD silicon nitride layer, or any other layer capable of acting as the hard mask for the formation layer. In this example, LTO is selected as the hard-mask layer 220 for masking the silicon etching and the thickness is 200-2000 Å determined by nature of the etching process.

An imaging layer 210 is provided on top of the hard mask layer 220 and may be formed of amorphous silicon (as is used in this particular example), silicon nitride, or any other material that has very different etching properties as compared to the layers beneath it. The imaging layer 210 is thick enough to provide protecting capability and thin enough to be easily eroded away or stripped during subsequent etch processes. Also, the contiguity of the imaging layer 210 with the hard-mask layer 220 must be good enough to forbid capillary-etching during the trimming process. For example, amorphous silicon and silicon dioxide layers may be chosen because they have good contiguity properties and etching selectivity.

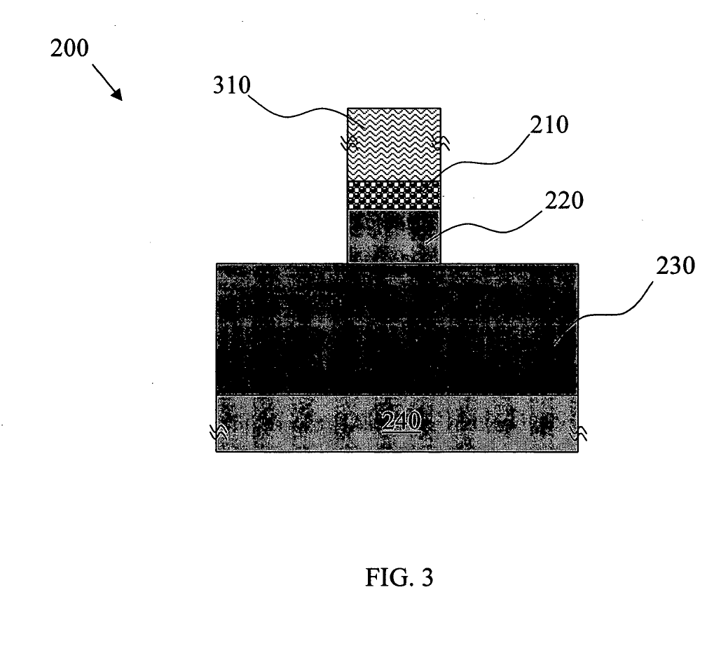

The imaging layer 210 and the hard-mask layer 220 can be patterned using a conventional lithographic technique as shown in FIG. 3. The imaging layer 210 and the hard-mask layer 220 can also be patterned using hard-mask etch stopper layer 310. Alternatively, the imaging layer 210 can serve as an etch mask for etching the hard-mask layer 220 without requiring the photoresist mask 310 on the top. For example, silicon nitride may be used as the imaging layer 210 and silicon dioxide is chosen as the hard-mask layer 220 for patterning silicon layer.

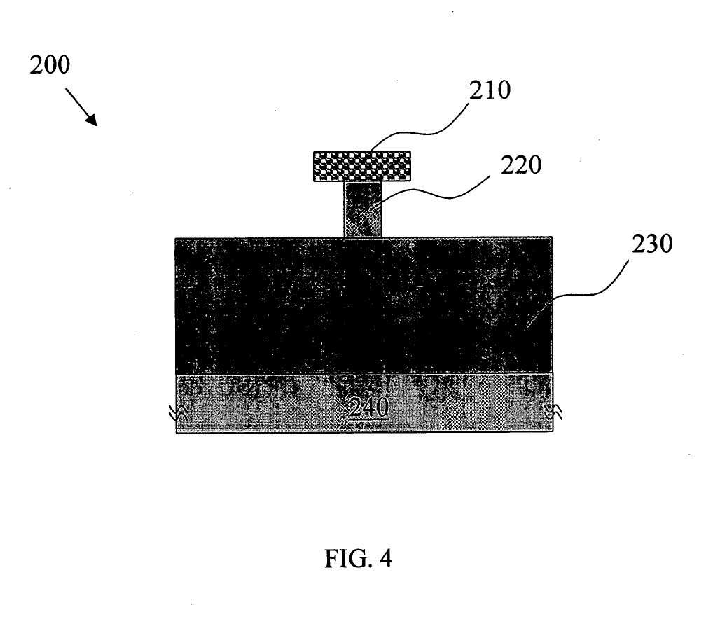

After patterning the imaging layer 210 and the hard-mask layer 220, the photoresist mask 310 (if provided) is removed and the trimming etching process can be performed as illustrated in FIG. 4. A trim etch slims the mask line formed by the hard-mask layer 220 using isotropic etch in a controlled manner in a wet etching system. The trim etch also can be performed in a high-density plasma (dry) etching system in a controlled manner. It should be noted that the trim etch has the effect of thinning the hard mask layer 220 to a thickness less than provided in the previous patterning step, and the resulting hard mask layer 220 is thinner than the remaining portion of the imaging layer 210 on top of the hard mask layer (see FIG. 4 in particular). After this isotropic etch, the imaging layer 210 is then stripped using a wet etching process or, alternatively, an anisotropic etch. The formation layer 230 is now exposed and can be patterned under the hard-mask 220. Generally the imaging layer will be removed before the etching of the formation layer. However, in some cases the imaging layer can be removed at the same time as the formation etch. This is the case, for example, if amorphous silicon is selected as the imaging layer 210 for patterning silicon material 230 and the imaging amorphous silicon need not be removed as a separate step and can be allowed to remain and then be automatically removed during the formation silicon etch.

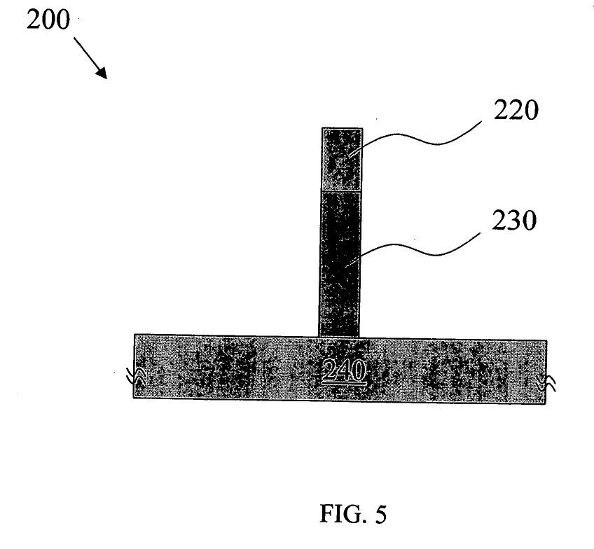

Referring now to FIG. 5, the formation layer 230 is selectively etched using the remaining portions of the trimmed hard-mask layer 220 to mask the pattern. Advantageously, the pattern created in the formation layer 220 includes widths that are less than one lithographic feature (ie the feature size defined by the lithography). Remaining portions of the formation layer 230 can serve as fin 130 or gate 140 structures as shown in FIG. 1. Advantageously, the fin 130 and gate 140 structures have a width or critical dimension of sub-20 nm and sub-50 mm respectively.

Subsequent to the formation of the ultra thin fin and/or gate structures as described above, conventional process steps may be used to finish the device structure are, such as source/drain doping, silicide, contact opening, and metallization.

The process described with reference to FIGS. 2-5 provides for the use of an imaging layer 210 and a trimming etch of hard-mask layer 220. The imaging layer 210 protects the hard-mask layer 220 during trim etch processes by protecting the surface and the fringe of the hard-mask during the trimming etching. Because the trimming-etch is isotropic, without protection of the imaging layer the hard-mask thickness will be reduced and the resultant hard-mask shape may be irregular. The created pattern has widths that are less than one lithographic feature, and the method provides a regular shape for the hard-mask which is very beneficial to the following process controls and operations.

It will thus be seen that there is provided a method for forming ultra-thin structures. This method includes depositing a hard-mask layer over the formation layer; depositing an imaging layer over the hard-mask layer; patterning the imaging layer and the hard-mask layer, which has very different etching selectivity property with other neighbor layers; using the imaging layer as a cap mask to selectively trim etch the hard-mask-layer with an isotropic etch in a controlled manner in wet or dry etching system to form a pattern smaller than produced by the imaging layer; removing the imaging layer; and etching the portions of the formation layer using the pattern formed by the hard-mask-layer.

This technique is particularly useful to the formation of the silicon fin and the polysilicon gate of modern sub-50 nm FinFET DG MOSFET, but the technique is not limited to those cases. It also can be applied to form other ultra-thin structures. Silicon dioxide can be selected as the hard-mask-layer material. While for the imaging layer for capping during the trimming etch, amorphous silicon can advantageously be used because it can be automatically removed when performing the silicon fin or polysilicon gate etching. There are also some other optional materials for these two layers, such as silicon nitride-silicon dioxide, amorphous silicon-silicon nitride, and etc, if the etching selectivity property is satisfied.

This capped trimming hard-mask (CTHM) method for ultra-thin dimension definition features many merits and improvements compared with conventional methods. Firstly, the process is simple and efficient, and only needs one conventional lithography step. There is no need to use double exposures such as partially-shifted resist patterning techniques, or direct writing electron-beam that is time consuming. Secondly, it is easy to control not only for the trimming etch but also for the definition of different dimensions. Unlike photoresist trimming (ashing), the hard-mask layer trimming etch is a wet (or dry) etch such that the etch-rate is more uniform and stable under optimized etching process design and control. Also because the pattern size is defined through lithography and trimming, it is easy to realize multiple-dimension fin width or gate length design that is impossible for the known spacer hard mask technique. Thirdly, the hard-mask shows a regular shape after the trimming etching process because it is protected by the capped imaging layer on top. During the trimming etching, the reaction only happens at the two sidewalls of the hard-mask pattern without affecting the top surface. This will provide great convenience in hard-mask removal and other processes due to the regular shape of the hard mask. All these three features, simple and efficient process, reliable and kindly controllability, and compatible and friendly to other processes, make this CTHM method very suitable for manufacture in forming ultra-small feature sized structures, such as fins and gates for FinFET devices.

1. A method of fabricating a semiconductor device comprising, providing a hard-mask layer over a formation layer that is to be patterned to form said device, depositing an imaging layer over the hard-mask layer, patterning the imaging layer and the hard-mask layer in sequence, trim etching the hard-mask layer to form a pattern smaller than that that the imaging layer had defined, and removing portions of the formation layer uncovered by the hard-mask pattern to form thin structures.

2. A method as claimed in claim 1, wherein the step of generating the hard-mask layer comprises thermal oxidation of a portion of a silicon formation layer.

3. A method as claimed in claim 1, wherein the step of generating the hard-mask layer comprises depositing a suitable material as the hard-mask layer on the formation layer.

4. A method as claimed in claim 1, wherein the step of patterning the imaging layer and the hard-mask layer includes using lithography or dry etch techniques to pattern these two layers into a single configuration.

5. A method as claimed in claim 1, wherein the step of trim etching the hard-mask layer comprises providing an isotropic wet etch to the hard-mask layer.

6. A method as claimed in claim 1 wherein the imaging layer and portions of the formation layer are removed by a single etching process.

7. A method as claimed in claim 1 wherein the imaging layer is removed to sufficiently expose the formation layer prior to removing portions of the formation layer.

8. A method as claimed in claim 1, wherein the imaging layer has a thickness between 500 and 2000 angstroms and the hard-mask layer has a thickness between 300 and 3000 angstroms.

9. A method of forming a fin structure in a FinFET semiconductor device in an integrated circuit comprising, providing a silicon layer, providing a hard-mask layer over the silicon layer, providing an imaging layer over the hard-mask layer, patterning the imaging layer and the hard-mask layer in sequence, trim etching the hard-mask layer to form a hard-mask line having a width less than that that the imaging layer had defined, and removing portions of the silicon layer to form fin structures.

10. A method as claimed in claim 9, wherein the material for the hard-mask layer has a different etching property from the silicon and the imaging layer material.

11. A method as claimed in claim 9, wherein the step of patterning the imaging layer and the hard-mask layer includes using lithography or dry etch techniques to pattern these two layers into a single configuration.

12. A method as claimed in claim 9, wherein the fin structures have a smallest dimension of 10-30 nm.

13. A method as claimed in claim 9, wherein the imaging layer has a deposited thickness of between 500 and 2000 angstroms and the hard-mask layer has a thickness of between 300 and 3000 angstroms.

14. A method of forming a gate structure in a semiconductor device in an integrated circuit, the method comprising, providing a gate material layer, depositing a hard-mask layer over the gate material layer, depositing an imaging layer over the hard-mask layer, patterning the imaging layer and the hard-mask layer in sequence, trim etching the hard-mask layer to form a hard-mask line has a width less than that that the imaging layer had defined, and removing portions of the gate material layer to form gate structures.

15. A method as claimed in claim 14, wherein the material for the hard-mask layer has a different etching property from the gate material layer and the imaging layer.

16. A method as claimed in claim 14, wherein the step of patterning the imaging layer and the hard-mask layer includes using lithography or dry etch techniques to pattern these two layers into a single configuration.

17. A method as claimed in claim 14, wherein the gate structures have a smallest dimension of 20-100 nm.

18. A method as claimed in claim 14, further comprising doping a substrate below the gate material layer to form active regions.

19. A method as claimed in claim 14, wherein the imaging layer has a deposited thickness between 500 and 2000 angstroms and the hard-mask layer has a deposited thickness between 300 and 3000 angstroms.

20. A method of preventing hard-mask-shape irregularization and pattern collapse during a trim etch process in the manufacture of a semiconductor device comprising, providing a hard-mask material layer over a formation layer that is to be patterned to form the device, depositing an imaging layer over the hard-mask material layer, patterning the imaging layer and the hard-mask layer in sequence, trim etching the hard-mask layer to form a hard-mask line having a width less than that that the imaging layer had defined, and removing portions of the formation layer uncovered by the hard-mask pattern to form thin structures.

21. A method as claimed in claim 20, wherein the material for the hard-mask layer has a different etching properties from the formation layer and the imaging layer material.

22. A method as claimed in claim 20, wherein the step of patterning the imaging layer and the hard-mask layer includes using lithography and dry etch techniques to pattern these two layers into a single configuration.

23. A method as claimed in claim 20, wherein the thin structures formed in the formation layer have a width of 10-100 nm.

24. A method as claimed in claim 20, wherein the imaging layer has a thickness between 500 and 2000 angstroms and the hard-mask layer has a thickness between 300 and 3000 angstroms.
